(19) United States
(12) Patent Application Publication
(10) Pub. No.: US 2011/0132657 A1
(43) Pub. Date: Jun. 9, 2011

(54) JUNCTION BOX

(76) Inventor: Raymond Brewer, Cambridgeshire (GB)

(21) Appl. No.: 13/058,390

(22) PCT Filed: Aug. 11, 2009
(86) PCT No.: PCT/GB2009/051002

§ 371 Date: Feb. 18, 2011

(30) Foreign Application Priority Data
Aug. 11, 2008 (GB) 0814594.8

(51) Int. Cl. H05K 5/00; H05K 13/00

(52) U.S. Cl. 174/520; 29/592.1

(57) ABSTRACT

A junction box for electrical cables comprising a main body comprising a base, an accepting wall with means for accepting cables through the wall, two walls substantially adjacent to the accepting wall and substantially opposite one another, and an electrical connector within the walls, wherein the means for accepting cables comprises at least two slots which are positioned one on either side of a central spacer and whose edges define with the adjacent spacer edges a cable gripping mechanism. Also provided is a method for using the junction box.

### FIELD OF THE INVENTION

This invention relates to electrical junction boxes.

### BACKGROUND TO THE INVENTION

Current United Kingdom Institution of Electrical Engineers (IEE) regulations state that electrical terminals shall not be subject to undue stress, that is, taking the weight of cables or fittings. Such regulations are likely to become more widespread over time. Furthermore, the stress placed on electrical terminals should be reduced where possible to reduce the risk of damage or fire.

A further problem with some known electrical junction boxes is that the cables are held loosely and may be pulled from the connector, thus fully disconnecting the cable or partially disconnecting the cable which presents a potential electrical hazard.

Known to the applicant are the following published patent specifications;
U.S. Pat. No. 5,068,495 A (Dahl-Bettermann-Winand)
U.S. Pat. No. 4,424,406 A (Slater et al)
U.S. Pat. No. 4,591,658 A (Bauer et al)

None of these provides a fully satisfactory solution to the problems outlined above.

The invention takes these known documents as its starting point.

### SUMMARY OF THE INVENTION

The scope of the invention is defined in the claims, the entire content of whose wording is hereby now incorporated into this present Summary by reference.

Generally, however, the invention is directed to a junction box for electrical cables comprising a main body comprising a wall with at least one inlet for cables through the body wall, and an electrical connector. The body further comprises a gripping mechanism comprising at least one moulded tapered tooth on a first side of the at least one inlet.

In one advantageous embodiment, the gripping mechanism may further comprise a biasing portion on a second side of the at least one inlet, to urge a cable onto the at least one moulded tooth. The biasing portion urges the cable against the teeth of the inlet to reduce possible movement of the cable within the at least one inlet.

Alternatively, the gripping mechanism may comprise at least one moulded tooth on a second side of the at least one inlet, opposite the first side, such that a cable may be held between the teeth. For cables with a larger girth, it may be desirable to remove the biasing portion and hold the cable between teeth on both sides of the at least one inlet to reduce possible movement of the cable through the at least one inlet.

The invention also extends to a junction box for electrical cables comprising a main body comprising a wall with at least one inlet for cables through the body wall. The junction box main body is provided with a compartment for holding a connector terminal block. The compartment holds the push-wire connector in place within the body of the junction box so that movement of the connector whilst within the junction box is reduced. Furthermore, the push-wire connector maybe removed from the compartment and replaced with another push-wire connector of a similar size.

Preferably, the push-wire connector terminal block may be positioned opposite the at least one inlet. By positioning the push-wire connector opposite the at least one inlet, the cables may be held in a substantially straight path such that the stress on the cable due to and curve in the cable between the inlet and the connector is reduced. This reduces the risk of the cable disconnecting from the connector and thus reduces the risk of electrical hazards within the junction box.

The invention includes within its scope a junction box substantially as described herein with reference to and as illustrated in any appropriate combination of the accompanying text and/or drawings.

### BRIEF DESCRIPTION OF THE DRAWINGS

An embodiment of the invention will now be described, by way of example only, and with reference to the accompanying drawings, in which:

FIG. 1 is a plan view of a junction box in accordance with the present invention;

FIG. 2 is a perspective view from one end of the junction box shown in FIG. 1; and

FIG. 3 is a perspective view from the opposite end of the junction box shown in FIG. 2.

### DETAILED DESCRIPTION OF EXEMPLARY EMBODIMENT

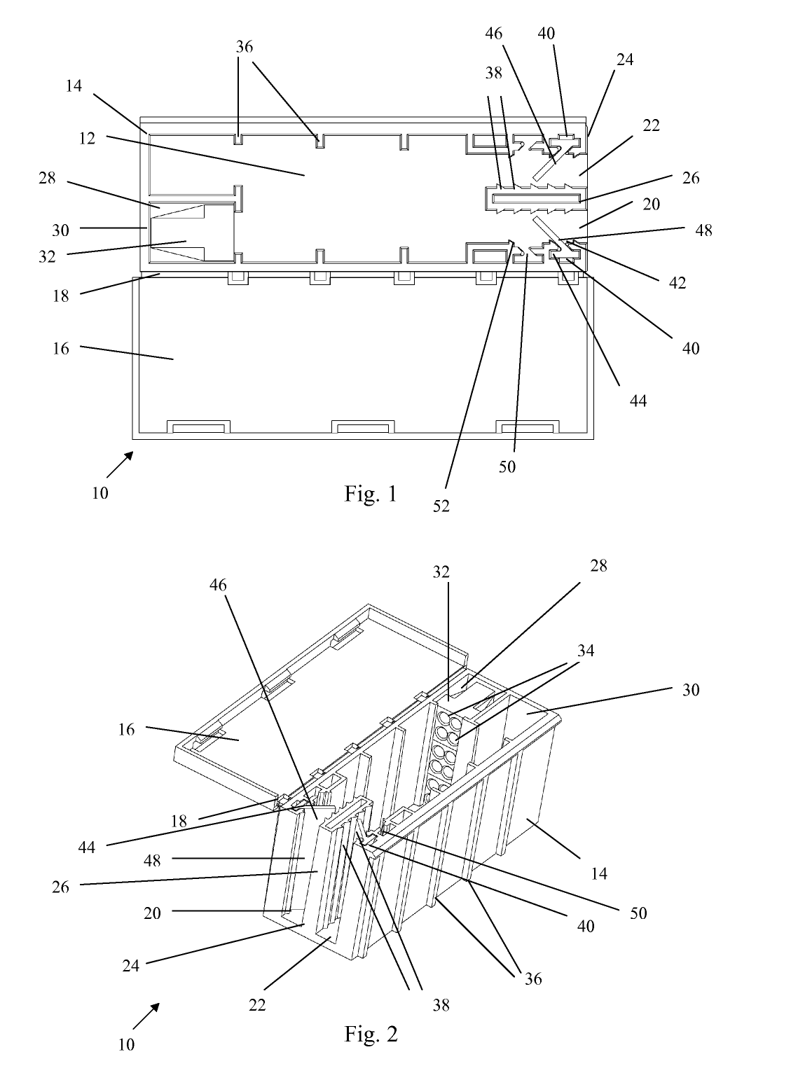

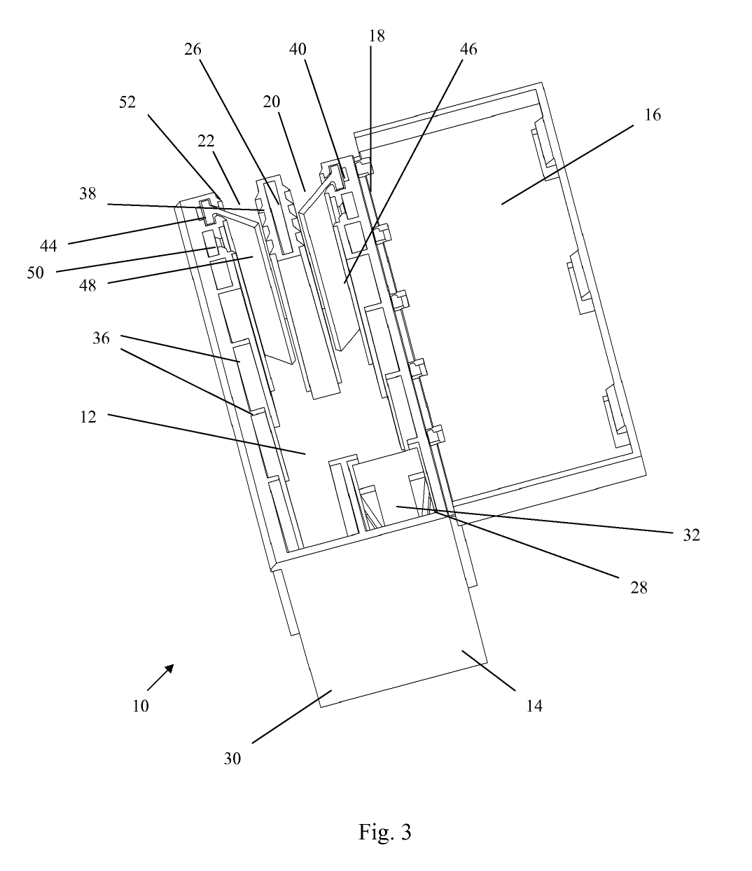

The Figures show a junction box 10, comprising a rectangular base 12, an outer wall 14 along the circumference of the base 12, and a lid 16. The lid 16 is connected to one of the long sides of the outer wall 14 by way of a living hinge 18. Seen in FIG. 2, is an in-line succession of three inwardly projecting tabs. When the lid is closed, each of these tabs embraces the underside of an equally visible lip along the top edge of the wall 14. This then locks the lid in place. The outer wall 14 is provided with a first inlet 20 and a second inlet 22, in the form of accepting slots, in a first short side 24 of the two short sides of the outer wall 14, separated by an inwardly directed rectangular spacer 26. The junction box 10 further comprises a compartment 28 with one side of the compartment 28 along the second short side 30 of the two short sides of the outer wall 14. The compartment 28 is shaped to receive and hold a push-wire connector terminal block 32, with the connection terminals 34 facing the inlets 20 and 22, such as a WAGO 773 push-wire connection or a WAGO 222 cage clamp connector (WAGO is currently a registered trademark). The junction box is provided with substantially vertical reinforcement strips 36 about its circumference.

The spacer 26 is provided with teeth 38, which are tapered, having a thinner end in the direction of the first short side 24 tapering to a thicker end in the direction of the second short side 30. The thicker end of each tooth 28 is substantially perpendicular to the spacer 26.

Biasing slots 40 are provided against each long side wall of the outer wall within the junction box 10 near the inlets 20 and 22, with an aperture 42 facing the spacer 26. A base portion 44 of a fin 46 is inserted into the biasing slot 40 and a blade portion 48 of the fin 46 extends through the aperture 42 across the inlet 20 or 22 towards the spacer 26. The blade portion 48 of the fin 46 is angled such that it extends away from the inlets 20 and 22 at an angle of substantially 45° from the first short wall 24 having the inlets 20 and 22.

Further biasing slots 50 are provided adjacent to the slots 40, against each long side wall of the outer wall within the junction box 10, with an aperture 42 facing the spacer 26. The further biasing slots 50 are positioned closer to the outside of the junction box 10 than the slots 40, and are shaped to accept the fins 46. However, when the fins 46 are held in the further slots 50, the gap between the fins 46 and the spacer 26 is increased.

The electrical junction box is of course in practical embodiments made of plastics material, such as polypropylene, and the base would thus be given certain amount of flex. If in use, the two longer sides are urged away from one another, with the lid open, this will flex the base and increase the width of the upper end of the accepting inlets 20 and 22. A first cable (not shown) to be connected to one of the terminals 34 of the push-wire connector 32 can then be fed down through the first inlet 20 into the box. The cable then passes through the body of the junction box 10 and is fitted into one of the terminals 34. The two longer sides of the box may then be released and as the sides come back together, the cable is held substantially straight between the first inlet 20 and the push-wire connector 32, such that cable is held in a position with reduced stress compared to many existing junction boxes. The substantially rigid fin 46 presses the cable, which would conventionally be encased in a resilient plastics sheath, against the tapered teeth 38, which allows the cable to pass into the junction box 10. The teeth 38 would then grip the resilient cable sheath and reduce the likelihood of it being pulled out of the junction box 10 back through the first inlet 20. Should the cable be pulled in back towards the first outlet 20, the fin 46 forces the cable against the teeth 38 and the thicker ends of the teeth 38 dig into the outside plastics material of the cable to reduce the likelihood of backward movement. This reduces the likelihood of the cable being pulled out of the terminal 34 of the push-wire connector 32.

If whilst the two longer sides are being urged apart, a second cable (not shown) is fed downwardly through the second inlet 22 and passes into the junction box 10 and is fitted into one of the terminals 34 of the push-wire connector 32, a second of the fins 46 holds the second cable in place against the teeth 38 in the same manner the first cable is held in the first inlet 20.

If multiple cables (not shown) are fed through each inlet 20 and 22 the cables can be stacked vertically one on top of the other within each inlet 20 and 22, allowing a plurality of cables to be connected to the push-wire connector 32 within the one junction box 10.

Alternatively, if the cable has a large girth, the fin 46 may be removed and the cable would then be gripped between the tapered teeth 38 on the spacer 26 and teeth 52 provided on the wall of in which the slots 40 are formed.

Once the cables are held in the junction box 14, the lid 16 can be closed and the locking mechanism would then hold the two longer walls in place to reduce the likelihood of the walls being urged apart which in use which would reduce the grip on the cables.

Whilst the invention has been described in relation to a rectangular junction box, it will be appreciated by a reader skilled in the art that the junction box may be another appropriate shape, for example circular, rectangular or hexagonal.

Modifications to the illustrated construction may occur to the reader familiar with the art without taking the device outside the scope of the present invention. For example, the fin blade may be divided so that it comprise a number of adjacent smaller blades or ‘fingers’ connected to the base portion of the fin so that multiple wires of different diameters can be forced against the teeth by the fin. The junction box may comprise more than two inlets or more than one push-wire connector. The lid may be attached by way of a different hinge system. The angle of the blade fin 46 may vary between being perpendicular to the slot 40 to being almost parallel with the slot 40.

1. A junction box for electrical cables comprising a main body comprising a base, an accepting wall with means for accepting cables through the wall, two walls substantially adjacent to the accepting wall and substantially opposite one another, and an electrical connector within the walls, wherein the means for accepting cables comprises at least two slots which are positioned one on either side of a central spacer and whose edges define with the adjacent spacer edges a cable gripping mechanism.

2. A junction box according to claim 1, wherein the base of the box is flexible to allow the width of the slots to be temporarily increased by pushing opposite walls that are adjacent the slots away from one another to allow cables to be inserted down into slots.

3. A junction box according to claim 1, wherein the box further comprises a lid portion, the lid portion comprising a hinge connecting it to a wall of the junction box, and locking means for releasably locking the walls adjacent the slots and thereby preventing them from moving away from one another.

4. A junction box according to claim 1, wherein at least one moulded tooth is tapered.

5. A junction boxy according claim 1, wherein the gripping mechanism further comprises a substantially rigid biasing portion facing the central spacer, to urge a cable onto the at least one moulded tooth.

6. A method of using a junction box as in claim 1 comprising forcing opposing walls in opposite directions to flex the flexible base and widen the slots, inserting cables into the slots, and releasing the opposing walls to allow the base to return to its original position and hold the cables securely in the slot.

7. A method according to claim 6, further comprising the step of closing a releasably lockable means to prevent divergent movement of the opposing walls.

8. (canceled)
